(19) United States
(12) Patent Application Publication
(10) Pub. No.: US 2016/0333263 A1
(43) Pub. Date: Nov. 17, 2016

(54) METHOD FOR PRODUCING A COMPOSITE MATERIAL CONTAINING LUMINESCENT MOLECULES, FOR RENDERING SUSTAINABLE THE ELECTROMAGNETIC CHARACTERISTICS OF SAID MATERIAL

(71) Applicants: LRPL (LABORATOIRE DE PHYSIQUE DU RAYONNEMENT ET DE LA LUMIÈRE), Paris (FR); CASCADE, Clamart (FR)

(72) Inventors: Philippe GRAVISSE, Paris (FR); Marc SCHIFFMANN, Vigneux De Bretagne (FR)

(73) Assignees: LRPL (LABORATOIRE DE PHYSIQUE DU RAYONNEMENT ET DE LA LUMIÈRE), Paris (FR); CASCADE, Clamart (FR)

(21) Appl. No.: 15/111,131

(22) PCT Filed: Jan. 13, 2015
(86) PCT No.: PCT/EP2015/050517

§ 371 Date: Jul. 12, 2016

(30) Foreign Application Priority Data
Jan. 13, 2014 (FR) 1450244

(51) Int. Cl. C09K 11/02; H01L 31/055; C09K 11/06

(52) U.S. Cl. CPC C09K 11/025; C09K 11/06; H01L 31/055; C09K 2211/10

(57) ABSTRACT

The invention relates to method for rendering sustainable the electromagnetic characteristics of optically active composite materials, said method comprising: a first step of preparing doped organic compounds by mixing at least one type of optically active molecules with a protective material in order to prevent the contact thereof with photodegradation-inducing elements and the migration of the optically active molecules; a second step of producing optically active nanoparticles including said doped organic compounds; and a third step of producing optically active composite materials by incorporating the optically active nanoparticles into a polymer matrix.

### CROSS-REFERENCE TO RELATED APPLICATIONS

This application is a National Phase Entry of International Application No. PCT/EP2015/050517, filed on Jan. 13, 2015, which claims priority to French Patent Application Serial No. 14/50244, filed on Jan. 13, 2014, both of which are incorporated by reference herein.

### FIELD

The present invention relates to a method for manufacturing a composite material containing luminescent molecules for making sustainable the electromagnetic characteristics of said material, as well as a product obtained by this method.

It relates more particularly to the field of composite materials doped by luminescent molecules, also defined hereinafter by the expression “optically active molecules”, abbreviated to OAMs.

### BACKGROUND AND SUMMARY

Luminescent or optically active molecules means molecules able to emit light after their peripheral electrons go into an excited state caused by a physical factor (absorption of light), mechanical factor (friction) or chemical factor.

An excited molecule may transmit its excitation to another adjacent molecule non-radiatively by coupling between the electron orbits of the two molecules. This phenomenon is referred to as resonance energy transfer resulting from a dipole-dipole interaction between two molecules. Resonance energy transfer is possible if the emission spectrum of one molecule partially overlaps the absorption spectrum of the other molecule. This type of energy transfer, referred to as the Foster type, is commonly referred to as FRET, the acronym for “Foster resonance energy transfer”.

“Light cascade” should be understood, within the meaning of the present patent, as the energy transfer occurring by association of a series of optically active molecules (OAMs) in two separate groups chosen so that the emission spectrum of the first group of OAMs partially overlaps the absorption spectrum of the second group of OAMs successively, each of the two groups of OAMs being defined by a re-emission wavelength different from the absorption wavelength of the OAMs in the group in question.

“Light cascade”, within the meaning of the present patent, may also incorporate “OAMs of the Stokes type” the re-emission wavelength of which is longer than the absorption wavelength, and “OAMs of the anti-Stokes type” the re-emission wavelength of which is shorter than the absorption wavelength.

The connection between the energy E and the wavelength λ is expressed by the following equation:

E=h·c/λ

h is the Planck constant, c is the speed of light in the vacuum.

The invention also relates to the manufacture of luminescent (or optically active) particles including luminescent (or optically active) molecules mixed in a protective material.

These optically active particles are integrated by dispersion in various types of polymer forming optically active composite materials, for example in the form of a film, for various industrial uses.

Depending on the type of polymer in the film, a plurality of uses is achieved by these optically active composite materials. In the first place, use such as photovoltaics (PV) can be obtained by a lamination technique—under a certain pressure and heat—with an encapsulation material such as for example ethylene vinyl acetate (EVA) polymer and all other related matrices, or by the technique of casting with polymethyl methacrylate (PMMA) and all other related matrices. In general terms, photovoltaic generators are manufactured in flat modules, which are integrated in buildings and greenhouses. Secondly, use as films for agricultural greenhouses is achieved by the technique of monoextrusion and coextrusion of low-density polyethylene (LDPE), PEBD/EVA or LLDPE for market-garden or horticultural greenhouses, for the cultivation of early fruit and vegetables, salads, lamb's lettuce or melons, and also rigid greenhouses made from PMMA, polycarbonate, PVC or NDLR.

In the prior art the principle of light cascades is known, which makes it possible, by doping a matrix with organic or mineral optically active substances, in a solution or in dispersion, to transfer all or part of the incident energy, in the wavelength bands with the greater sensitivities of an electromagnetic sensor, such as photovoltaic cells for example.

The French patent FR 2792460 is known in the prior art, describing a photovoltaic generator comprising at least one photovoltaic cell and a transparent matrix deposited with at least one optically active material having an absorption wavelength λₐ and a re-emission wavelength λᵣ, the optically active material being chosen so that λₐ corresponds to a range of lesser sensitivity of the photovoltaic cell than λᵣ, the matrix comprising a reflective coating.

The American patent U.S. Pat. No. 4,952,442 is known, describing a light cascade doped film for agricultural greenhouses so that the light is enhanced in the frequency bands favourable to photosynthesis and so that the yield of the plants is appreciably improved thereby.

The patent application FR 1000696 describes a photovoltaic module for an agricultural greenhouse comprising a front plate intended to be in contact with the sunlight, a rear substrate and a set of photovoltaic cells disposed between the front plate and the rear substrate. The photovoltaic module has a cell packing factor approximately between 0.2 and 0.8 and comprises at least one layer of light cascade doped material promoting photosynthesis able to absorb sunlight in at least one range of wavelengths in order to re-emit it in at least a second range of wavelengths favourable to photosynthesis of at least one plant species.

The French patent FR 7808150 describes a polymer matrix based on a homogeneous mixture of optically active crystals of the rare earth type capable of generating a light cascade, which emits photons in the infrared region. This polymer matrix shifts the incident light near to the greater sensitivity of a photocell.

The solutions of the prior art have problems of stabilisation of the optically active molecules. Although the various doped polymeric organic matrices of the organic or inorganic optically active molecules give advantageous energy conversion efficiencies, the effective of ageing of these doped matrices is significant and the colour fastness to light is insufficient.

One possible cause is the photo-oxidation of the optically active molecules, which is related to the high permeability of polymers to gases, in particular oxygen or ozone. These polymers are usually employed for photovoltaics, for example in the EVA family, and for agricultural greenhouse films, for example in the PE family. This ageing effect is accelerated by electromagnetic radiation, such as UV rays. Oxygen and UV radiation—a component of solar energy—produce on the OAMs a combined effect, which causes a rise in temperature leading to a greater sensitivity to photo-oxidation.

In order to solve this problem, antioxidant, anti-UV, HALS—heat and light stabilisers—and adjuvants of the phosphite, phosphorite or anti-static type are generally added to polymer films such as EVA and PE. However, despite the reduction in ageing, the number of effective charges—OAMs—per unit volume is substantially limited.

The other cause of ageing of the films is the migration of the optically active molecules into the PE/EVA matrices, which exude PE/EVA with the plasticisers and create a localised overconcentration. This aggregation leads to a phenomenon of auto-extinction due to a high local concentration of optically active molecules.

In other organic polymeric matrices doped with rare earths, the ageing effect is limited. Nevertheless, the energy conversion yields are too low to permit industrial and commercial use.

Another difficulty stems from the shifting of the absorption and emission spectra of the OAMs, when they are in the presence of a solvent. A certain number of environmental parameters in the solvent may modify the spectra of these molecules: the pH, the presence of organic solutes, the temperature and the polarity of the solvent. The effects of these parameters vary from one type of OAM to the other type. Such a type of effect also occurs on molecules with a large dipole.

The invention aims to solve the problems of the prior art, in particular to guarantee an advantageous energy conversion efficiency, while delaying the ageing of the optically active molecules.

To do this, it is proposed to overcome the effects of migrations, photo-oxidation and photodegradation of the OAMs in non-polar polymers, which have low permeability to gas.

For this purpose, the present invention proposes an improvement to the morphology of the support matrices with respect to the dopants of the optically active molecules.

To this end, the subject matter of the present invention is a method intended to render sustainable the electromagnetic characteristics of the optically active composite materials, comprising:
a first step of preparing doped organic compounds by mixing at least one type of optically active molecule with a protective material in order to prevent contact thereof with elements causing photodegradation and migration of the optically active molecules,
a second step of manufacturing optically active nanoparticles including said doped organic compounds,
and a third step of producing optically active composite materials by integrating the optically active nanoparticles in a polymer matrix.

According to the features of the invention, said protective material consists of at least one type of polar polymer crosslinked in three dimensions, and which has low permeability to gas.

According to advantageous particularities, the invention provides optically active nanoparticles having a diameter of between 1.10⁻⁸ metres and 2.10⁻⁶ metres.

According to a first variant embodiment, the optically active nanoparticles are inorganic.

According to a second variant, the optically active nanoparticles are organic, in one embodiment the organic nanoparticles are produced by latex colloidal method from methyl methacrylate, in another embodiment the organic nanoparticles are produced by mechanical micronisation method.

According to a preferred embodiment of the invention, only one type of optically active molecule is mixed with a protective material and doped in the nanoparticles in order to obtain the optically active nanoparticles doped as a unit.

Preferably, a set of said optically active nanoparticles doped as a unit are associated in accordance with an optimised concentration rule in order to achieve the light cascade effect and integrated in the polymers in order to form an optically active composite material.

According to a particularly advantageous embodiment, a plurality of types of optically active molecules associated in accordance with an optimised concentration rule for the light cascade effect are mixed in at least one type of protective material and doped in the nanoparticles in order to obtain the optically active nanoparticles doped with light cascade.

Preferably, said optically active nanoparticles doped with light cascade are integrated in the polymers in order to form an optically active composite material.

A plurality of said optically active composite materials with different functions are stacked at the time of coextrusion of the films forming a matrix.

In one embodiment, the emission spectrum of one type of OAM partially overlaps the absorption spectrum of another type of OAM successively forming a light cascade, and the C₂/C₁ ratio between the concentration C₁ of the first type with respect to the concentration C₂ of the second type is between 0.13 and 0.26.

More particularly, the optically active composite materials include at least one type of Stokes optically active molecules the re-emission wavelength of which is longer than the absorption wavelength and/or at least one type of anti-Stokes optically active molecules the re-emission wavelength of which is shorter than the absorption wavelength.

According to another embodiment, optically active molecules of the organic fluorophore type having a remanence of less than 10 ns are associated with the optically active crystals of the inorganic ZnS.Ag type having remanence greater than 10 ns, the emission and absorption wavelengths of which respond to the light cascade effect.

The optically active composite materials having according to the invention sustainable optoelectronic-magnetic characteristics comprise the doped optically active nanoparticles of the optically active molecules, which are mixed with the protective materials.

The invention also relates to an application of said optically active composite material for industrial uses such as photovoltaics or the films of agricultural greenhouses.

The protective material is often an organic polymer of the polar type and crosslinked in three dimensions, which has low permeability to oxygen. These characteristics help to resist ageing and to increase the colour fastness to light of the organic matrices doped by OAMs in order to prevent photodegradation and migration of the OAMs in the families of matrices of the PE and EVA type.

The nanoparticles have large interface surfaces and high effective cross sections. This is because a uniform dispersion of the active particles of submicron size leads to an appreciable increase in the degree of adsorption of the doped organic compounds of OAMs for a given load mass. Therefore a significant increase in the number of OAMs per unit volume for a given volume fraction.

The invention thus relates to:
a method for manufacturing a luminescent composite material intended to render sustainable the electromagnetic characteristics of this luminescent material, comprising:
a first step of preparing an organic compound with protected luminescent molecules by mixing at least a first group of luminescent molecules with a protective material in order to prevent contact thereof with elements causing photodegradation and migration of the luminescent molecules,
a second step of manufacturing luminescent particles having a diameter of between 1.10⁻⁸ metres and 2.10⁻⁶ metres including said organic compounds,
and a third step of producing a luminescent composite material by integrating the luminescent particles in a polymer matrix.
According to this method:
   the protective material consists of at least one polar polymer compatible with the luminescent molecules, preferably physically and chemically stable.
The step of manufacturing said luminescent particles consists of micronising the organic compound by grinding.
The step of manufacturing said luminescent particles consists, during the manufacture of the organic compound, of initially introducing the at least first group of luminescent molecules into a monomer in order to form a luminescent polymer, integrating this polymer with an inorganic particle, and then evaporating the polymer while leaving the luminescent molecules fixed to the inorganic support so as to form the luminescent particles.
The step of manufacturing said luminescent particles consists of manufacturing organic particles and dissolving the at least first group of luminescent molecules in the organic particles formed so as to form the luminescent particles.
The organic nanoparticles are produced by latex colloidal method from methyl methacrylate.
Each luminescent particle comprises the same type of luminescent molecules, which are able to react with light cascade with a second type of luminescent molecule of a second group of luminescent particles or each luminescent particle comprises various types of luminescent molecule able to react in pairs with light cascade.
The concentrations of the various types of luminescent molecule of the various groups of luminescent particles are optimised in order to produce the light cascade effect.
The polymer matrix is in the form of a film.
The composite material comprises a plurality of films each integrating luminescent particles, these films being stacked one on top of the other in order to combine the effects of the luminescent particles that they contain.
The stacking of the films is carried out at the time of a step of coextrusion of the films.
The luminescent molecules (OAMs), where the emission spectrum of one type of OAM partially overlaps the absorption spectrum of another type of OAM forming successively a light cascade, comply with the ratio C₂/C₁ between the concentration C₁ of a first type with respect to the concentration C₂ of a second type of between 0.13 and 0.26.
The luminescent molecules include at least one type of Stokes molecule the re-emission wavelength of which is longer than the absorption wavelength and/or at least one type of anti-Stokes optically active molecule the re-emission wavelength of which is shorter than the absorption wavelength.
The luminescent molecules include at least molecules of the organic fluorophore type having a remanence of less than 10 ns and are associated with the optically active crystals of the inorganic ZnS.Ag type having a remanence greater than 10 ns, the emission and absorption wavelengths of which respond to the light cascade effect.
The invention relates to a material obtained according to the above method.
As well as a material comprising luminescent particles of PMMA doped by luminescent molecules produced by latex colloidal method from MMA monomers.
And the use of the material according to the preceding claim as a photovoltaic element or an agricultural greenhouse film.

### BRIEF DESCRIPTION OF THE DRAWINGS

The invention will be understood better and other features and advantages will emerge more clearly from a reading of the following description referring to the accompanying drawings, where

FIG. 1 shows the emission spectra of the samples of doped PMMA microspheres of the formula P004NP obtained under the excitation of UV light with a wavelength of 365 nm,

FIG. 2 shows the comparison of the emission spectra of samples produced in different ways, obtained under the excitation of UV light with a wavelength of 365 nm.

### DETAILED DESCRIPTION

Other particularities and advantages of the invention will emerge from a reading of the description given below of particular embodiments of the invention, given by way of indication but non-limitatively.

In order to achieve the “light cascade” effect between a plurality of separate groups of OAMs, it is necessary to fulfil three conditions between two groups of OAM in order to obtain the “Foster resonance energy transfer” phenomenon, abbreviated to FRET:
The emission spectrum of a molecule of a first group partially overlaps the absorption spectrum of a molecule of the second group,
The distance separating the two molecules respectively in the two groups is less than 1.8×R₀, R₀ is the distance between the two molecules respectively in the two groups for which the energy transfer efficacy is 50%,
The relative orientation between the two molecules respectively in the two groups makes it possible to define a dipole.

The structure of the molecule and the number of rings may determine the absorption and emission wavelengths of molecules. The optically active molecules in a first group are selected so that the emission ranges of these molecules correspond to the absorption ranges of the molecules in the second group, in order to fulfil the first criterion.

According to one embodiment of the invention, the optically active molecules are of the organic scintillinator luminophore type with N+1, N+2, N+3, N+x phi rings chosen from: aromatic rings, anthracene, naphthacene, pentacene, hexacene, rhodamine, oxazine, diphenyloxazole and dimethyloxazole.

According to another embodiment, the OAMs include at least one group of Stokes OAMs and at least one group of anti-Stokes OAMs. In this case, it is possible to use molecules including rare-earth atoms as anti-Stokes OAMs. They may form, when associated with organic polymeric matrices, luminescent organic polymeric matrices since they are doped with rare earths that give a good channel for exploiting the anti-Stokes effects. This is because the optically active crystals that can form organic polymeric matrices doped with rare earths are in general able to produce an inverse light cascade. For example, a molecule absorbing two photons in the infrared region is capable of emitting a photon in the visible region. This is thus the case, for example, with anti-Stokes luminescences with three Ln202S: Er(sup 3+), Yb(sup 3+), which are luminophores incorporated in triplex under the excitation of IR sources in the various ranges of 0.93, 1.53 and 1.59 micrometres. Further details are given in the following table:

| | | | Emission | |
|---|---|---|---|---|
| Formulae | Components | Excitation (μm) | (μm) | Rdt % |
| FCD-660-2 | Y203-YOF: Er, Yb | 0.90-0.98 | 0.64-0.68 | 2.0 |
| FCD-660-3 | YOCl: Er, Yb | 0.90-0.98 | 0.64-0.68 | 3.0 |
| FCD-660-4 | YbOCl: Er | 0.90-0.98 | 0.64-0.68 | 3.0 |

In a third particularly advantageous embodiment, a first group of optically active molecules (OAMs) of the organic fluorophore type having a remanence<10 ns is associated with a second group of OAMs of the inorganic photoluminescent/optically active crystal type (series ZnS doped Ag or Cu) having a remanence>10 ns, the molecules in the two groups having respectively emission and absorption wavelengths responding to the light cascade effect. The remanence of the light cascade becomes of longer duration (>10 ns) and the effect of re-emission of energy by the fluorophores then takes place over a longer time.

The following table describes the various possible electron transitions of the molecules.

| Transition | Name of process | Lifetime |
|---|---|---|
| S(0) => S(1) or S(n) | Absorption | 10⁻¹⁵ |
| S(n) = singlet state of level n | (excitation) | |
| S(n) => S(1) | Internal conversion | 10⁻¹⁴ to 10⁻¹⁰ |
| S(1) => S(1) | Vibrational relaxation | 10⁻¹² to 10⁻¹⁰ |
| S(1) => S(0) | Fluorescence | 10⁻⁹ to 10⁻⁷ |
| S(1) => T(1) | Intersystem change | 10⁻¹⁰ to 10⁻⁸ |
| T(1) = triplet state | | |
| S(1) => S(0) | Non-radiative | 10⁻⁷ to 10⁻⁵ |
| | relaxation quenching | |
| T(1) => S(0) | Phorphorescence | 10⁻³ to 10⁻² |
| T(1) => S(0) | Non-radiative | 10⁻³ to 10⁻² |
| | relaxation quenching | |

A transition is often made between the excited state of the first level and the fundamental state.

In order to fulfil the second criterion, it is necessary to achieve a certain concentration of OAMs. By way of example, the following table shows two examples of formulae, composition and concentration of the OAMs in g/kg or as a percentage: the first formula P004NP dosed at 21 g/kg, the second formula 2013F dosed at 5 g/kg.

| | PPO 2.5 | | LFR305// | GG |
|---|---|---|---|---|
| | diphenyl | Uvitex OB 2.5 | OR610 | Hostasol |
| Reference | oxazole | thiophene | diperylene | red |
| compounds | C15H11NO | C26H26N202S | C32H16 | C23H12OS |
| Formula | 15.4 g | 3.85 g | 0.8744 g | 0.8744 g |
| P004NP | 73.33% | 18.33% | 4.166% | 4.166% |
| Formula | 3.657 g | 0.942 g | 0.401 g | |
| 2013F | 73.14% | 18.84% | 8.02% | |

The doped organic compounds are obtained by a mixture of a protective material of the polymethyl methacrylate (PMMA) type, which is physically and chemically stable, and optically active molecules. PMMA is polar, since it effectively aligns the dipole molecules and produces a LC effect statistically more prominent than isotope materials. However, the absence of shifting of the spectrum must be regularly checked.

In the doped organic compounds, the protective material of the polymethyl methacrylate type may be replaced by another type of protective material: other polar polymers (or ones made polar by an electron bombardment or functionalisation of the polymer molecules) compatible with the optically active molecules, for example polyesters, methylenebut-3-en-1-ol (IOH), polycarbonate (PC), silicone and methyl methacrylate (MMA).

A protective material suitable for producing organic compounds with protected luminescent molecules is physically and chemically stable, polar and compatible with the luminescent molecules in question, that is to say it prevent exudation, migration, photo-oxidation and photodegradation of this OAM.

These doped organic compounds are next grafted in nanoparticles of the type explained below having high effective cross-sections forming optically active nanoparticles (OANs).

A large interface surface area associated with micro- or nanometric dimensions is the main element differentiating nanoparticles from traditional charges. The specific surface areas of certain charges may attain values of between 500 and 1000 m²/g in the case of lamellar charges (montmorillonite). the degree of adsorption relating to the interface is then all the greater.

To produce the optically active composite materials, the optically active nanoparticles are integrated in polymers for industrial use, which are chosen from:
polymethyl methacrylate (PMMA),
ethylene vinyl acetate (EVA) polymer
polyvinylchloride (PVC)
polycarbonate (PC) or low-density polyethylene (LDPE),
polyvinylidine fluoride (PVDF).

The above paragraphs describe in general the method for producing the optically active composite materials, while the following paragraphs relate in particular to the various methods for producing optically active nanoparticles.

1. Inorganic Nanoparticles

According to a first variant embodiment, the optically active nanoparticles are inorganic and are produced for example from aluminosilicate, mesoporous silica, alumino zeolite or aluminosilicates.

It is advantageous in this case to be able to prepare as required:
(a) a first type of doped nanoparticle each solely in a first group of OAMs, and a second type of doped nanoparticle in the same second group of OAMs able to function with light cascade with the OAMs of the first type of nanoparticle, or
(b) doped nanoparticles each individually in two groups of OAMs able to react together with light cascade.

1. a) Inorganic Nanoparticles Doped by a Single Type of OAM

A description is given below of an example embodiment of doped nanoparticles solely of the same first group of OAMs:

According to a first step, a first doped solution of a first group of OAMs is manufactured by effecting the dissolution of optically active molecules (OAMs) in a first group in an ad hoc ligand or MMAs that bind the OAM to zeolite. The OAMs in this first group may for example be chosen from phi N-ring polycyclic aromatic hydrocarbons (anthracene or benzene series):
3 phi polycyclic aromatic hydrocarbon,
4 phi polycyclic aromatic hydrocarbon,
5 phi polycyclic aromatic hydrocarbon etc.

Other doped solutions of groups of OAMs other than those characterising the above first group are manufactured according to the same method, choosing the OAMs of the solution prepared according to their ability to create a light cascade effect with the OAMs of the first solution.

According to a second step, each solution prepared with the same type of OAM is introduced into functionalised inorganic nanoparticles of the zeolite type with a magnetic agitator at a temperature of 45° C. in order to obtain the various groups of OANs (optically active nanoparticles) that are LC (light cascade) doped. Then the ad hoc ligand or the MMA is evaporated in order to obtain various groups of optically active nanoparticles each doped by the same type of OAM fixed to the inorganic nanoparticles. Finally, these LC-doped OANs are dried and integrated in the encapsulation polymer matrices.

According to a third step, each type of 3, 4, 5 or N phi doped inorganic OANs respectively are associated with a polymer matrix, in optimised concentrations for producing the light cascade effect, most suited to the application sought: PV—photovoltaic—or PS—photosynthesis.

This produces the effects of reinforcing the colour fastness to light and resistance to ageing.

1. b) Inorganic Nanoparticles Doped by a Plurality of Types of OAM

A description is given hereinafter of an example embodiment of doped nanoparticles each individually in at least two groups of OAMs able to react in pairs with light cascade.

According to another embodiment of the invention, a plurality of types of OAM with optimised concentrations and proportions for the light cascade effect sought are introduced into a ligand or MMAs for example, in order to form a light-cascade (LC) solution.

Next, this solution is introduced into the inorganic nanoparticles of the zeolite type in a magnetic agitator at a temperature of 45° C. in order to obtain the LC (light cascade) doped OANs. Then the ad hoc ligand or the MMA is evaporated. Finally, these LC-doped OANs are dried and integrated in the encapsulation matrices.

Photon diffusion effects, reinforcement of the colour fastness to light and resistance to ageing occur.

The method for manufacturing inorganic particles is known to persons skilled in the art. For example, the French patent EP 1335879 describes the manufacture of a zeolite material containing dye. The publication in the scientific journal “Matériaux microporeux et mesoporeux” (volume 145, issues 1-3, November 2011, pages 157-164) describes the adsorption behaviour of methylene blue on modified clinoptilolite.

2) Organic Nanoparticles

According to a second variant embodiment, the optically active nanoparticles are organic. The techniques for manufacturing organic nanoparticles relate historically to colloidal chemistry and involve conventional sol-gel processes, or other aggregation processes.

These wet-chemistry techniques currently offer nanoparticles of better quality.

Producing organic nanoparticles from polymethyl methacrylate (PMMA) in a colloidal solution by latex method starting from MMA (the monomer of PMMA) by different methods is known.

For example, in the scientific journal “Macromolecular Rapid Communications”, a description is given of the synthesis of nanometric polymethyl methacrylate initiated by 2,2-azo-isobutyronitrile by polymerisation in differential microemulsion; in the scientific journal “Polymer” (volume 49, number 26, 8 Dec. 2008, pages 5636-5642), a description is given of nanocomposites of polymethyl methacrylate and silica produced by reversible-addition “grafting through” by polymerisation chain transfer addition-fragmentation.

2) a) Organic Nanoparticles Doped by a Single Type of OAM

According to a first step, the optically active molecules (OAMs) are dissolved in a colloidal solution by latex method starting from the PMMA monomer. With a magnetic agitator and at a temperature of 45° C., OANs from a few tens to a few hundreds of nm are obtained. Each type of unitary OAN comprises a single type of OAM.

According to a second step, a plurality of groups of doped organic OANs respectively of a plurality of types of different OAMs, each OAN having the same type of OAM, are mixed in a dual-screw extruder with PEBD/EVA compounds, in accordance with a concentration rule optimised for obtaining the light cascade effect sought.

2) b) Organic Nanoparticles Doped by a Plurality of Types of OAM

According to another embodiment of the invention, a plurality of types of OAM, for example luminophores of the 2, 3, 4, N phi HAP type at concentrations and proportions optimised for the light cascade effect, are introduced into a colloidal solution by latex method starting from MMA (monomer of PMMA), with a magnetic agitator and at a temperature of 45° C. in order to obtain the LC-doped OANs. These LC-doped OANs are next mixed with the PMMA polymer or with the PEBD/EVA compounds in a dual-screw extruder.

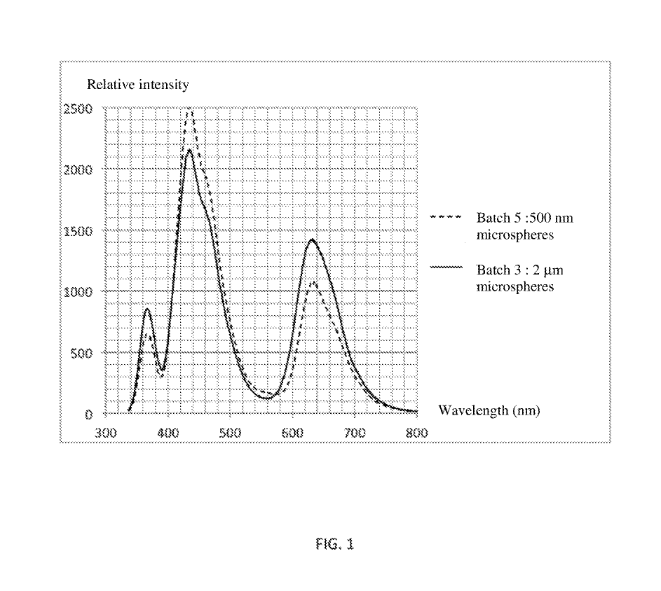

By this method of producing LC-doped OANs, OANs of 500 nm and 2 micrometres doped according to the LC P004NP formula were obtained, the analysis results of which are shown in FIG. 1.

FIG. 1 contains the emission spectra of the samples of PMMA microspheres doped according to the P004NP formula under the excitation of UV light with a wavelength of 365 nm. The PMMA microspheres doped here are produced by latex colloidal method from MMA as explained in the preceding paragraphs. The X-axis represents the wavelength in nanometres, 100 nanometres per graduation, while the Y-axis represents the intensity in an arbitrary unit. The solid line represents the batch 3 sample of microspheres of size 2 micrometres, while the broken line represents the batch 5 sample of microspheres of size 500 nanometres.

The following table shows the intensities of the peak in the red light and blue light region respectively. This table makes it possible to easily classify the productions in terms of energy conversion effectiveness.

| | Blue (430-435 nm) | Red | Blue/red ratio |
|---|---|---|---|
| Batch 3 (2 μm) | 2122 | 1408 (627 nm) | 2.044 |
| Batch 5 (500 nm) | 2496 | 1038 (629 nm) | 2.404 |

It is batch 3 that is the most effective for photovoltaics.

Batch 5 can be envisaged for agricultural applications since it is very effective in the blue region while being significant in re-emission in the red region.

The optically active molecules grafted in the optically active nanoparticles of PMMA have increased colour fastness to light and good resistance to UV and O2.

3. Nanoparticles Issuing from the Grinding of Doped PMMA

According to a third variant embodiment, an LC-doped PMMA matrix is micronised by grinding in order to form an organic pigment. The matrix is formed by a rigid or flexible organic material, or is in a form of a coating that can be applied in the form of a resin. The organic material is polymethyl methacrylate (PMMA) for example.

The LC-doped PMMA matrices are micronised by grinding to 40/50 micrometres. It is a “top down” method that reduces the size of the particles by ball or planetary-movement grinders.

The optically active dopants are organic pigments with 2, 3, 4, N+1 phi rings of the aromatic ring type, or of the anthracene, naphthacene, pentacene, hexacene, rhodamine, oxazine, diphenyloxazole or dimethyloxazole type. The particles thus obtained are referred to as organic pigments.

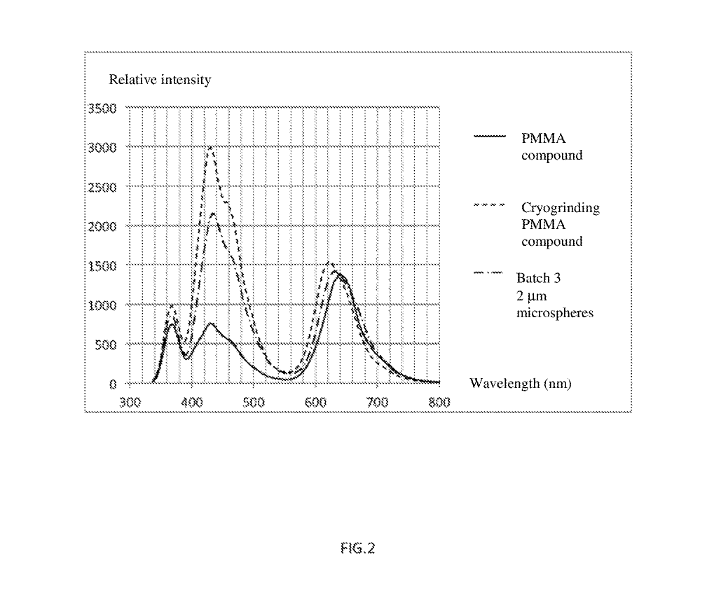

FIG. 2 shows the comparison between the emission spectra of the samples produced in different ways under the excitation of UV light with a wavelength at 365 nm. The first type is the doped PMMA compound of the formula 2013F before the micronisation process; the second type is the doped PMMA compound of the formula 2013F after the cryogrinding micronisation process; while the third type is the batch 3 sample (the doped microspheres of the formula P004NP of size 2 micrometres).

The X-axis represents the wavelength in nanometres, 100 nanometres per graduation, while the Y-axis represents the relative intensity in arbitrary units. The solid line represents the doped PMMA compounds, the broken line represents the cryogrinding PMMA compounds, while the dot-and-dash line represents the batch 3 sample—the 2-micrometre microspheres.

In the blue region, the intensity of the emission peak 2-micrometre microspheres of batch 3 is less than 27% compared with the peak of the cryoground PMMA. In the red region, the intensity of the emission peaks is of the same order for the 2013F doped PMMA compound, the cryoground 2013F doped PMMA compound and the 2-micrometre microspheres of batch 3 (P004NP doped). However, a slight difference exists in wavelength of the peaks between the three:
the 2013F doped PMMA compound: 634 nm,
the cryoground 2013F doped PMMA compound: 617 nm,
the 2-micrometre microspheres of batch 3: 628 nm.

The organic pigments thus obtained are associated with the polymer matrices that are usual in the industrial applications concerned: films for agricultural greenhouses or in polyvinyl chloride (PVC), ethylene vinyl acetate (EVA) polymer or polycarbonate (PC) sheets.

The novel performance for delaying ageing of the LC-doped PMMA in the EVA matrix is measured by durability using the “Atlas Suntest XLS+” machine under the following test conditions applied:
60 W/m² and 300-400 nm;
continuous light;
102 minutes dry, 18 minutes rainy;
temperature: 65°+/−2° C.

The materials are exposed under these conditions for 1500 hours and no degradation appears. Consequently the equivalent durability under natural conditions is estimated to be greater than 10 years, whereas without the invention it would last only one month in EVA or LC-doped PE with MOAs. The effect of delaying ageing is therefore verified.

It is possible to produce the final composite material that includes the optically active nanoparticles or luminescent particles described in paragraphs 1) to 3) above, and a polymer matrix of the PMMA, EVA, PVC, PEBD or PVDF type, by extrusion.

The nanoparticles of the above type and the polymer matrix monomers are introduced into the extruder in order to obtain an extruded film at the output.

It is also possible to coextrude various films each including particular functionalities by using the corresponding OAMs: according to the application sought, it is possible to alternate, at the time of coextrusion, films forming a matrix, the functionalities of the exterior, internal (central core) and interior films. For example, in a greenhouse, an anti-UV and anti-O₂ function will be chosen in an exterior film, the light-cascade OAM doping in the central core, and the anti-mist function in the interior film. It is also possible to vary the light-diffusion and IR-reflecting functions and the thicknesses of the films according to the applications.

4. Composite Material Issuing from a Copolymer, One of which is Doped

According to a fourth variant embodiment, a composite material is formed by a PMMA-PE/EVA copolymer, where the PMMA is the polar polymer doped by the OAMs, forming a light cascade.

This type of material is the addition of two different polymers, one technical and functional and forming an agricultural film or the PE/EVA photovoltaic encapsulation, the other optically active, such as PMMA doped by micronised OAMs.

Any other type of matrix associated with any other type of organic pigment, such as IOH or PC, is compatible.

1. A method for manufacturing a luminescent composite material intended to render sustainable the electromagnetic characteristics of this luminescent material, comprising:
a first step of preparing an organic compound with protected luminescent molecules by mixing at least a first group of luminescent molecules with a protective material in order to prevent contact thereof with elements causing photodegradation and migration of the luminescent molecules,
a second step of manufacturing luminescent particles having a diameter of between 1.10-8 metres and 2.10-6 metres including said organic compounds,
and a third step of producing a luminescent composite material by integrating the luminescent particles in a polymer matrix.

2. A method according to claim 1, wherein the protective material is formed by at least one polar polymer compatible with the luminescent molecules.

3. A method according to claim 1, wherein the step of manufacturing said luminescent particles comprises micronising the organic compound by grinding.

4. A method according to claim 1, wherein the step of manufacturing said luminescent particles comprises, when the organic compound is manufactured, of initially introducing the at least first group of luminescent molecules into a monomer in order to form a luminescent polymer, integrating this polymer with an inorganic particle, and then evaporating the polymer while leaving the luminescent molecules fixed to the inorganic support so as to form the luminescent particles.

5. A method according to claim 1, wherein the step of manufacturing said luminescent particles comprises manufacturing organic particles and dissolving the at least first group of luminescent molecules in the organic particles formed so as to form the luminescent particles.

6. A method according to claim 1, wherein the organic nanoparticles are produced by latex colloidal method from methyl methacrylate.

7. A method according to claim 1, wherein each luminescent particle comprises the same type of luminescent molecules, which are able to react in light cascade with a second type of luminescent molecule in a second group of luminescent particles or each luminescent particle comprises various types of luminescent molecule able to react in pairs with light cascade.

8. A method according to claim 7, wherein the concentrations of the various types of luminescent molecule in the various groups of luminescent particles are optimised in order to produce the light cascade effect.

9. A method according to claim 1, wherein the polymer matrix is in the form of a film.

10. A method according to claim 9, wherein the composite material comprises a plurality of films each integrating luminescent particles, these films being stacked on top of one another in order to combine the effects of the luminescent particles that they contain.

11. A method according to claim 10, wherein the stack of films is produced at the time of a step of coextrusion of the films.

12. A method according to claim 1, wherein the luminescent molecules (OAMs), where the emission spectrum of one type of OAM partially overlaps the absorption spectrum of another type of OAM forming successively a light cascade, comply with the ratio C2/C1 between the concentration C1 of a first type with respect to the concentration C2 of a second type of between 0.13 and 0.26.

13. A method according to claim 1, wherein the luminescent molecules include at least one type of molecule of the Stokes type the re-emission wavelength of which is longer than the absorption wavelength and/or at least one type of anti-Stokes optically active molecule the re-emission wavelength of which is shorter than the absorption wavelength.

14. A method according to claim 1, wherein the luminescent molecules include at least one of the molecules of the organic fluorophore type having a remanence of less than 10 ns and are associated with the optically active crystals of the inorganic ZnS.Ag type having a remanence greater than 10 ns, the emission and absorption wavelengths of which respond to the light cascade effect.

15. A luminescent composite material comprising:
an organic compound including protected luminescent molecules comprising at least a first group of luminescent molecules and a protective material operable to prevent contact thereof with elements causing photodegradation and migration of the luminescent molecules;
the luminescent particles having a diameter of between 1.10-8 metres and 2.10-6 metres including the organic compounds; and
the luminescent particles being in a polymer matrix.

16. A material comprising luminescent particles of PMMA doped by luminescent molecules produced by latex colloidal method from MMA monomers.

17. The material according to claim 16 being a photovoltaic element.

18. The material according to claim 16 being an agricultural greenhouse film.
